(19) United States
(12) Patent Application Publication
(10) Pub. No.: US 2011/0309439 A1
(43) Pub. Date: Dec. 22, 2011

(54) SEMICONDUCTOR DEVICE AND METHOD FOR MANUFACTURING THE SAME

(75) Inventors: Tomoko Matsudai, Tokyo (JP); Koichi Endo, Tokyo (JP); Kumiko Sato, Hyogo-ken (JP); Norio Yasuhara, Kanagawa-ken (JP)

(73) Assignee: KABUSHIKI KAISHA TOSHIBA, Tokyo (JP)

(21) Appl. No.: 13/052,254

(22) Filed: Mar. 21, 2011

(30) Foreign Application Priority Data
Jun. 21, 2010 (JP) 2010-140237

(51) Int. Cl. H01L 29/78; H01L 21/336

(52) U.S. Cl. 257/336; 438/291; 257/E29.266; 257/E21.437

(57) ABSTRACT

According to one embodiment, a semiconductor device includes a semiconductor substrate, a first conductivity-type region, a second conductivity-type source region, a gate insulating film and a gate electrode. The first conductivity-type region is provided in an upper layer portion of the semiconductor substrate. The second conductivity-type source region and a second conductivity-type drain region are arranged by being separated from each other in an upper layer portion of the first conductivity-type region. The gate insulating film is provided on the semiconductor substrate. The gate electrode is provided on the gate insulating film. An effective concentration of impurities in a channel region corresponding to a region directly below the gate electrode in the first conductivity-type region has a maximum at an interface between the gate insulating film and the channel region, and decreases toward a lower part of the channel region.

### CROSS-REFERENCE TO RELATED APPLICATIONS

This application is based upon and claims the benefit of priority from the prior Japanese Patent Application No.2010-140237, filed on Jun. 21, 2010; the entire contents of which are incorporated herein by reference.

### FIELD

Embodiments described herein relate generally to a semiconductor device and a method for manufacturing the same.

### BACKGROUND

Lateral Diffusion Metal-Oxide-Semiconductor (LDMOS) has been known as a Metal-Oxide-Semiconductor Field-Effect Transistor (MOSFET) formed in a semiconductor device. LDMOS can satisfy breakdown voltage levels requested in varieties of applications by using easy techniques for adjusting the length of device. In recent years, there has been increasing the application of fine processing and fine-design rules, similar to Complementary Metal-Oxide-Semiconductor (CMOS also to LDMOS), also to LDMOS. Through the application of the fine process and the fine-design rules to LDMOS similar those to CMOS at an equivalent or a finer degree, the reduction in ON-resistance, the increase in speed of LDMOS and furthermore, mixed mounting with fine CMOS become possible. However, since LDMOS has a complex structure compared with CMOS, the influence of process variation factors upon property variations becomes larger when LDMOS becomes fine.

### BRIEF DESCRIPTION OF THE DRAWINGS

FIG. 1 is a cross-sectional view illustrating a semiconductor device according to a first embodiment;

FIG. 2 is a graph illustrating a profile of concentration of impurities in the channel region in the first embodiment;

FIGS. 3A and 3B, FIGS. 4A and 4B, FIGS. 5A and 5B, and FIG. 6 are process cross-sectional views illustrating a method for manufacturing the semiconductor device according to the first embodiment;

FIG. 7 is a graph illustrating the influence of the variation of film thickness of the gate insulating film on the threshold value of LDMOS;

FIG. 8 is a graph illustrating a profile of concentration of impurities in the channel region of comparative examples;

FIG. 9 is a process cross-sectional view illustrating a method for manufacturing a semiconductor device according to a second embodiment; and

FIG. 10 is a cross-sectional view illustrating a semiconductor device according to a third embodiment.

### DETAILED DESCRIPTION

In general, according to one embodiment, a semiconductor device includes a semiconductor substrate, a first conductivity-type region, a second conductivity-type source region, a gate insulating film and a gate electrode. The first conductivity-type region is provided in an upper layer portion of the semiconductor substrate. The second conductivity-type source region and a second conductivity-type drain region are arranged by being separated from each other in an upper layer portion of the first conductivity-type region. The gate insulating film is provided on the semiconductor substrate. The gate electrode is provided on the gate insulating film. An effective concentration of impurities in a channel region corresponding to a region directly below the gate electrode in the first conductivity-type region has a maximum at an interface between the gate insulating film and the channel region, and decreases toward a lower part of the channel region.

In general, according to one other embodiment, a method is disclosed for manufacturing a semiconductor device. The method can include forming a first conductivity-type region in an upper layer portion of a semiconductor substrate. The method can include forming a gate insulating film on the semiconductor substrate. The method can include forming a gate electrode on the gate insulating film. The method can include forming a channel implanting region by introducing impurities into a region directly below the gate electrode in the first conductivity-type region via the gate insulating film. In addition, the method can include forming a second conductivity-type source region and a second conductivity-type drain region in regions on both sides of a region corresponding to the region directly below the gate electrode in an upper layer portion of the first conductivity-type region. The introducing the impurities is conducted so that a profile of a concentration of the impurities along a vertical direction has a peak in the gate insulating film.

Various embodiments will be described hereinafter with reference to the accompanying drawings.

A first embodiment will be described in the following.

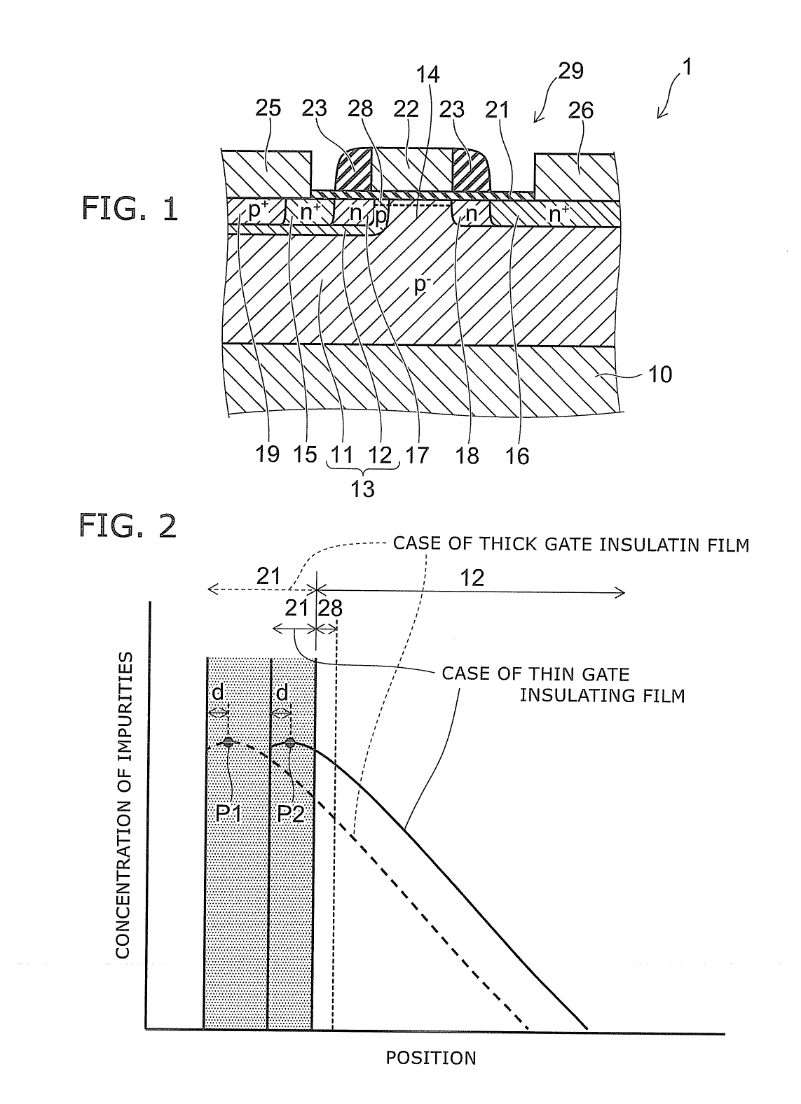

FIG. 1 is a cross-sectional view illustrating a semiconductor device according to the embodiment.

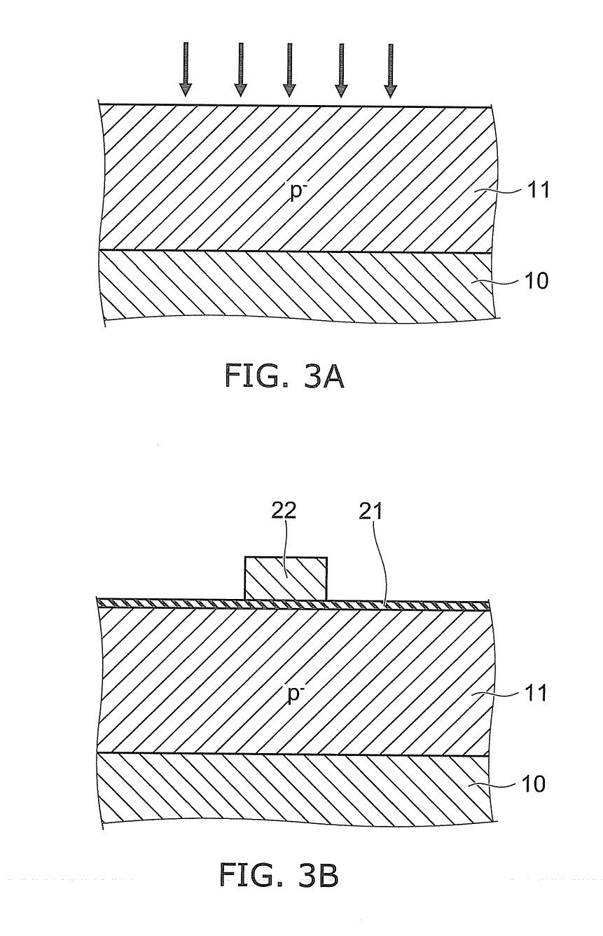

FIG. 2 is a graph illustrating a profile of concentration of impurities in the channel region in the embodiment; the horizontal axis is position in the depth direction of device, and the vertical axis is the concentration of impurities.

As illustrated in FIG. 1, a semiconductor device 1 according to the embodiment has a semiconductor substrate 10 made up of, for example, silicon. A p-type well 11 having p⁻-type conductivity is formed in a part of an upper layer portion on the semiconductor substrate 10, and a p-type channel implanting region 12 is formed in a part of an upper layer portion on the p-type well 11. The effective concentration of impurities in the channel implanting region 12 is higher than those in the p-type well 11. Meanwhile, the term “effective concentration of impurities” referred to the specification signifies the concentration of impurities contributing to the conduction of semiconductor material. When, for example, the semiconductor material contains both impurities serving as donors and impurities serving as acceptors, the concentration signifies the concentration of activated impurities excluding the offset of donors and acceptors.

An n⁺-type source region 15 is formed in a part of an upper layer portion on the channel implanting region 12, and an n⁺-type drain region 16 is formed at an upper layer portion on the p-type well 11 and outside the channel implanting region 12. That is, the source region 15 and the drain region 16 are respectively formed as an upper layer portion above the semiconductor substrate 10 while being separated from each other.

Furthermore, an n-type Lightly Doped Drain (LDD) region 17 is formed in a part of an upper layer portion on the channel implanting region 12. The LDD region 17 is positioned between the source region 15 and the drain region 16, and is in contact with the source region 15. The effective concentration of impurities in the LDD region 17 is lower than those in the source region 15. In contrast, an n-type drift region 18 is formed at an upper layer portion on the p-type well 11 and outside the channel implanting region 12. The drift region 18 is positioned between the drain region 16 and the source region 15, and is in contact with the drain region 16. The LDD region 17 and the drift region 18 are separated from each other, and a part of the p-type well 11 and a part of the channel implanting region 12 are positioned between the LDD region 17 and the drift region 18. Furthermore, a p⁺-type back-gate region 19 is formed at an upper layer portion on the channel implanting region 12 and at the side opposite to the drain region 16 viewed from the source region 15. The back-gate region 19 is in contact with the source region 15. The effective concentration of impurities in the back-gate region 19 is higher than those in the channel implanting region 12. A p-type region 13 (a first conductivity-type region) is structured by the p-type well 11 and the p-type channel implanting region 12 excluding the portions of the source region 15, the drain region 16, the LDD region 17, the drift region 18, and the back-gate region 19.

Above the semiconductor substrate 10, there is provided a gate insulating film 21 made up of, for example, silicon oxide. The gate insulating film 21 is provided directly on the LDD region 17, the drift region 18, and a portion between the LDD region 17 and the drift region 18. On the gate insulating film 21, there is provided a gate electrode 22 made of, for example, a polysilicon containing impurities introduced. The gate electrode 22 is positioned directly on a portion between the LDD region 17 and the drift region 18. On side surfaces of the gate electrode 22, there are provided side walls 23 made up of, for example, silicon nitride. The LDD region 17 and the drift region 18 are positioned directly below the respective side walls 23. Consequently, directly below the gate electrode 22, there is positioned a region of the p-type well 11 between the LDD region 17 and the drift region 18. The region in the p-type region 13 corresponding to the portion directly below the gate electrode 22 is hereinafter referred to as the “channel region 14”. Further, the channel implanting region 12 is positioned in a part of the channel region 14 at the source region 15 side. The effective concentration of impurities in the channel implanting region 12 is higher than those in the p-type well 11, and thus, in the channel region 14, the effective concentration of impurities in the part of source region 15 side is higher than those in the part of drain region 16 side.

Furthermore, at a part directly on the source region 15 and the back-gate region 19, no gate insulating film 21 is provided, but a metallic source electrode 25 is provided. The source electrode 25 is in contact with the source region 15 and the back-gate region 19, and establishes an ohmic contact thereto. Moreover, at a part directly on the drain region 16, no gate insulating film 21 is provided, but a metallic drain electrode 26 is provided. The drain electrode 26 is in contact with the drain region 16, and establishes ohmic contact thereto.

An n-type LDMOS 29 is formed of the channel region 14, the source region 15, the drain region 16, the LDD region 17, the drift region 18, the back-gate region 19, the gate insulating film 21, the gate electrode 22, the side walls 23, the source electrode 25, and the drain electrode 26. When the LDMOS 29 entered ON-condition, an n-type inversion layer is formed in the uppermost layer portion of the channel region 14. Hereinafter the region where the inversion layer is formed is referred to as the “inversion layer-forming region 28”.

According to the embodiment, in the channel implanting region 12 and the gate insulating film 21 provided directly thereon as illustrated in FIG. 2, the profile of effective concentration of impurities along the vertical direction (the depth direction of device) has a single peak (maximum value), and the peak appears in the gate insulating film 21. As a result, the effective concentration of impurities in the channel implanting region 12 becomes the largest at the interface with the gate insulating film 21, and then monotonously decreases toward lower positions. The effective concentration of impurities in the channel implanting region 12 is higher than those in the p-type well 11, and thus the average value of the effective concentration of impurities in the channel region 14 within horizontal plane becomes the largest at the interface with the gate insulating film 21 and monotonously decreases toward lower positions. Furthermore, when the average value of effective concentration of impurities in the horizontal plane is determined in the gate insulating film 21 at a portion directly on the channel region 14 and in the channel region 14, and when the profile of the average value in the vertical direction is drawn, the peak of the profile appears in the gate insulating film 21.

Next will be the description about the method of manufacturing semiconductor device according to the embodiment.

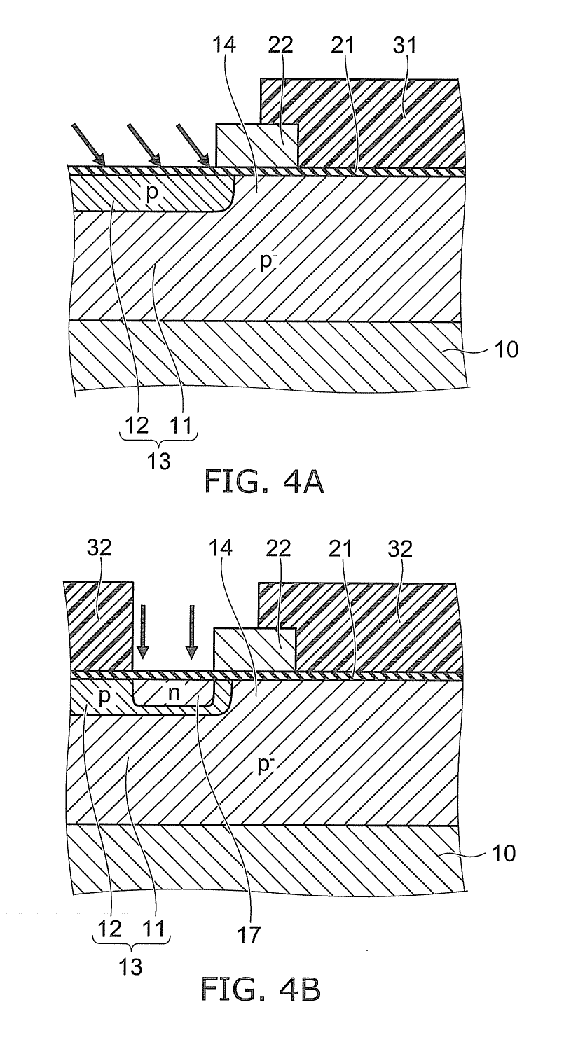

FIGS. 3A and 3B, FIGS. 4A and 4B, FIGS. 5A and 5B, and FIG. 6 are the process cross-sectional views illustrating a method for manufacturing the semiconductor device according to the embodiment.

First, as illustrated in FIG. 3A, the semiconductor substrate 10 made up of, for example, silicon is prepared. Next, by locally introducing impurities serving as acceptors into the semiconductor substrate 10, the p-type well 11 is formed in a part of an upper layer portion on the semiconductor substrate 10.

Then, as illustrated in FIG. 3B, the gate insulating film 21 made up of, for example, silicon oxide, is formed above the semiconductor substrate 10. At this moment, the thickness of the gate insulating film 21 unavoidably varies within a certain range caused by a process factor such as oxidation time. Then, a polysilicon is deposited on the gate insulating film 21 to form a conductive film. By processing the conductive film, the gate electrode 22 is formed on a part of the gate insulating film 21.

Then, as illustrated in FIG. 4A, a resist pattern 31 is formed on the gate insulating film 21. The resist pattern 31 covers one side of the LDMOS 29 centering on the gate electrode 22, or covers a portion for forming the drain region 16 (refer to FIG. 1) and the like, (hereinafter referred to as the “drain-side region”), while exposing the opposite side of the LDMOS 29, or a portion for forming the source region 15 (refer to FIG. 1) and the like, (hereinafter referred to as the “source-side region”). The resist pattern 31 covers the portion of the drain region 16 side of the gate electrode 22, while exposing the portion of the source region 15 side.

Next, the gate electrode 22 and the resist pattern 31 are used as the mask, and ion implantation of impurities as an acceptor is conducted. The ion-implantation is conducted in a direction tilting toward the source region 15 (refer to FIG. 1) relative to a direction normal to the upper surface of the semiconductor substrate 10 (hereinafter referred to as the “vertical direction”). That is, the impurities are introduced in a tilted direction, from above the source side to the drain side downwards. By the operation, the impurities are introduced into the semiconductor substrate 10 via the gate insulating film 21, and the channel implanting region 12 is formed in a part of an upper layer portion on the p-type well 11. At this moment, since the impurities are introduced in a tilted direction, the channel implanting region 12 is formed also in a portion of the region directly below the gate electrode 22. The energy for introducing impurities is set and adjusted to a low level so that the profile of concentration of impurities in the vertical direction has a peak in the gate insulating film 21. By the adjustment, the concentration of impurities in the channel implanting region 12 becomes the largest at the top surface, or at the interface with the gate insulating film 21, and then decreases toward low positions. The p-type region 13 is formed by the p-type well 11 and the channel implanting region 12. Furthermore, a portion of the p-type region 13 corresponding to the region directly below the gate electrode 22 becomes the channel region 14. After that, the resist pattern 31 is removed.

Then, as illustrated in FIG. 4B, a resist pattern 32 is formed on the gate insulating film 21. The resist pattern 32 is formed so as to open at a portion of source region 15 side of the gate electrode 22, and to open at a region adjacent to the source region 15 side viewed from the gate electrode 22. Then, the gate electrode 22 and the resist pattern 32 are used as the mask, and ion implantation of impurities as donors is conducted. The ion implantation is carried out in almost vertical direction. By the implantation, the n-type conductivity LDD region 17 is formed in self-aligning mode in a region at a part of an upper layer portion on the channel implanting region 12 and in a region adjacent to the region directly below the gate electrode 22. After that, the resist pattern 32 is removed.

Then, as illustrated in FIG. 5A, a resist pattern 33 is formed on the gate insulating film 21. The resist pattern 33 is formed so that the source-side region of the LDMOS 29 is covered and the drain-side region 16 is exposed. Furthermore, the resist pattern 33 covers the source region 15 side of the gate electrode 22, while exposing the drain region 16 side thereof. Next, with the gate electrode 22 and the resist pattern 33 as the mask, impurities serving as donors are introduced in almost vertical direction. This allows the n-type conductivity drift region 18 to be formed in self-aligning mode in a region of drain region 16 side viewed from the channel region 14 (refer to FIG. 1) and in a region adjacent to the region directly below the gate electrode 22. After that, the resist pattern 33 is removed.

Then, as illustrated in FIG. 5B, an insulating material such as silicon nitride is deposited on the entire surface of the gate insulating film 21, followed by etch-backing to cause the insulating material only on the side surface of the gate electrode 22 to remain. By the operation, the side walls 23 are formed on both side surfaces of the gate electrode 22. Then, a resist pattern 34 is formed on the gate insulating film 21. The resist pattern 34 is formed so as to cover a region in which the back-gate region 19 of LDMOS 29 will be formed (refer to FIG. 1), while exposing a region for forming the source region 15 and the drain region 16, and exposing the gate electrode 22 and the side wall 23.

Next, the gate electrode 22, the side walls 23, and the resist pattern 34 are used as the mask, and ion implantation of impurities serving as donors are conducted in almost vertical direction. By the implantation, the impurities serving as donors are introduced in duplication into a portion other than the portion directly below the side wall 23 in the LDD region 17, that is, into a portion distant from the gate electrode 22 in the LDD region 17, and thus the n⁺-type conductivity source region 15 is formed. In contrast, the impurities are not introduced into the LDD region 17 at a region corresponding to the portion directly below the side wall 23, which thus causes the region as the LDD region 17 to remain. Furthermore, the impurities serving as donors are introduced in duplication into a portion other than the portion directly below the side wall 23 in the drift region 18, that is, into a portion distant from the gate electrode 22 in the drift region 18, and thus the n⁺-type conductivity drain region 16 is formed. Meanwhile, the impurities are not introduced into the drift region 18 at a portion corresponding to the portion directly below the side wall 23, which thus causes the portion as the drift region 18 to remain. Through the operation, relative to the side walls 23, there are formed in self-aligning mode the source region 15, the drain region 16, the LDD region 17, and the drift region 18. After that, the resist pattern 34 is removed.

Then, as illustrated in FIG. 6, there is formed a resist pattern 35 that exposes a region where the back-gate region 19 will be formed, while covering other regions. The resist pattern 35 is used as the mask, and ion implantation of impurities serving as acceptors is conducted in the vertical direction. By this operation, the back-gate region 19 is formed in a part of an upper layer portion on the channel implanting region 12 and at a region contacting with the source region 15. After that, the resist pattern 35 is removed.

Then, as illustrated in FIG. 1, among the gate insulating films 21, a portion corresponding to a region directly on the source region 15 and the back-gate region 19, and a part corresponding to a region directly on the drain region 16 are removed. Next, a metallic film is deposited on a region where the gate insulating film 21 is removed, and thus the source electrode 25 is formed in a part of portion directly on the source region 15 and the back-gate region 19, and then the drain electrode 26 is formed in a part of portion directly on the drain region 16. By this operation, the semiconductor device 1 is manufactured.

Next will be the description about the operations and effects of the embodiment.

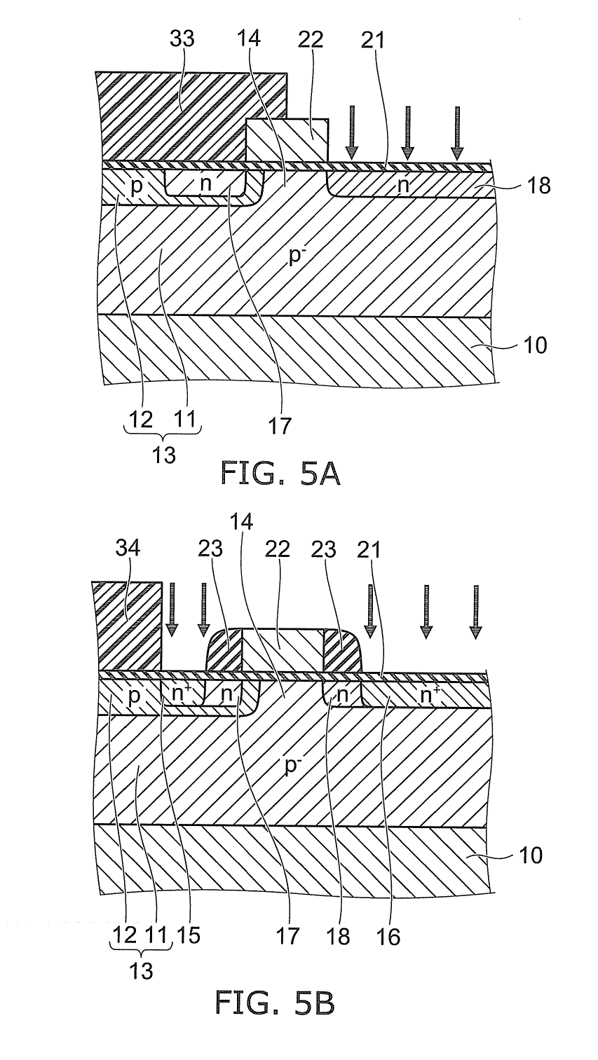

FIG. 7 is a graph illustrating the influence of the variation of film thickness of the gate insulating film on the threshold value of LDMOS; the horizontal axis is the concentration of impurities in the inversion layer-forming region, and the vertical axis is the threshold value of LDMOS.

As described above, the inversion layer-forming region 28 (refer to FIG. 1) signifies the uppermost layer portion of the channel region 14.

As illustrated by C-C′ line in FIG. 7, the variation in film thickness of the gate insulating film 21 results in the variation in the threshold value (Vth) of the LDMOS 29 even when the effective concentration of impurities in the inversion layer-forming region 28 is the same. In concrete terms, when the film thickness of the gate insulating film 21 increases, the threshold value of the LDMOS 29 increases. In contrast to this, when the concentration of impurities in the inversion layer-forming region 28 varies, the threshold value of the LDMOS 29 varies even when the thickness of the gate insulating film 21 is the same. In concrete terms, increase in the concentration of impurities in the inversion layer-forming region 28 increases the threshold value. Since the channel implanting region 12 including the inversion layer-forming region 28 is formed by introducing impurities via the gate insulating film 21, as illustrated in FIG. 4A, the concentration of impurities in the inversion layer-forming region 28 depends on the thickness of the gate insulating film 21.

Therefore, the embodiment is designed so as to suppress the fluctuation of threshold value of LDMOS even when the thickness of the gate insulating film varies by positively utilizing the influence of both the film thickness of the gate insulating film and the concentration of impurities in the inversion layer-forming region on the threshold value of LDMOS, and the influence of film thickness of the gate insulating film on the concentration of impurities in the inversion layer-forming region.

That is, in the process of FIG. 4A, in introducing impurities serving as acceptors to an upper layer portion of the p-type well 11 via the gate insulating film 21, the acceleration voltage of ion implantation is adjusted so as to cause the peak of the profile of concentration of impurities in the vertical direction (in the depth direction of device) to position in the gate insulating film 21. By the adjustment, if the acceleration voltage of ion implantation of the impurities is kept constant, the peak position is distant from the upper surface of the gate insulating film 21 by a certain distance d. Therefore, based on the interface between the semiconductor substrate 10 and the gate insulating film 21, the position of peak P1 of the profile of concentration of impurities in the case of thick gate insulating film 21 is above the position of peak P2 of the profile of concentration of impurities in the case of thin gate insulating film 21. In this case, viewed from the inversion layer-forming region 28, the peak P1 is positioned more distant than the peak P2. The concentration of impurities in the inversion layer-forming region 28 becomes low in the case of thick gate insulating film 21 compared with the case of thin gate insulating film 21. Consequently, as shown by A-A′ line in FIG. 7, there offsets the effect of increasing the threshold value caused by the thickened gate insulating film 21 and the effect of decreasing the concentration of impurities in the inversion layer-forming region caused by the thickened gate insulating film 21 to thereby decrease the threshold value caused by the decrease in the concentration of impurities. As a result, the fluctuation of threshold value of LDMOS 29 (ΔVth) can be minimized.

The above effects will be described below comparing with comparative examples.

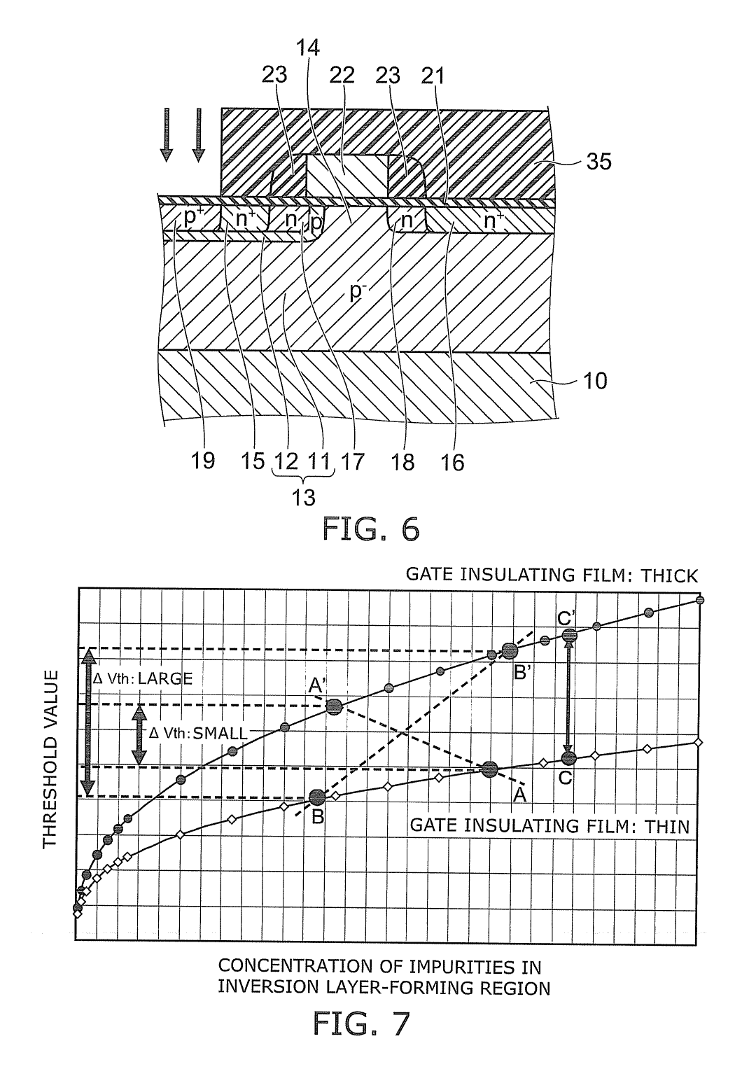

FIG. 8 is a graph illustrating a profile of concentration of impurities in the channel region of the comparative examples; the horizontal axis corresponds to the position in the depth direction of device, and the vertical axis corresponds to the concentration of impurities.

In the comparative example, illustrated in FIG. 8, the peak of the profile of concentration of impurities in the vertical direction of the channel implanting region 12 and the gate insulating film 21 positioned directly on the channel implanting region 12 is located in the channel implanting region 12. Also in this case, the peak position is distant from the upper surface of the gate insulating film 21 by almost a constant distance d. Therefore, based on the interface between the semiconductor substrate 10 and the gate insulating film 21, the position of peak P1 of the profile of concentration of impurities in the case of thick gate insulating film 21 is above the position of peak P2 of the profile of concentration of impurities in the case of thin gate insulating film 21. Since, however, the peak P1 and the peak P2 are positioned at the semiconductor substrate 10 side, the peak P1 becomes closer to the inversion layer-forming region 28 than the peak P2 does. Consequently, the concentration of impurities in the inversion layer-forming region 28 becomes larger in the case of thick gate insulating film 21 than in the case of thin gate insulating film 21. As a result, as given by B-B′ line in FIG. 7, there is duplicated the effect of increasing the threshold value caused by thickening the gate insulating film 21 and the effect of increase in the concentration of impurities in the inversion layer-forming region 28 caused by thickening the gate insulating film 21 to increase the threshold value. Consequently, the fluctuation of threshold value, (ΔVth), increases.

In contrast to this, according to the first embodiment, the peak of the profile of concentration of impurities appears in the gate insulating film, and thus the distance between the inversion layer-forming region and the peak increases and the concentration of impurities in the inversion layer-forming region decreases as the thickness of the gate insulating film becomes larger. As described above, the increase in the thickness of the gate insulating film and the decrease in the concentration of impurities in the inversion layer-forming region adversely affect the threshold value and thus, according to the embodiment, the fluctuation of threshold value of LDMOS can be suppressed even when the film thickness of the gate insulating film varies.

Furthermore, according to the semiconductor device 1 of the embodiment, the drift region 18 which has lower effective concentration of impurities than those of the drain region 16 is provided at the source region 15 side viewed from the drain region 16 so as to contact with the drain region 16. By the structure, when a reverse bias voltage is applied between the source region 15 and the drain region 16, the drift region 18 is depleted to thereby relax the electric field. As a result, the withstand voltage of the LDMOS 29 increases. By adjusting the effective concentration of impurities and the lateral length of the drift region 18, a desired withstand voltage requested to the LDMOS 29 can be attained. Depending on the withstand voltage requested to the LDMOS 29, the effective concentration of impurities and the lateral length of the drift region 18 may be the same as those of the LDD region of CMOS which is mounted together with the LDMOS 29 on the semiconductor device 1. Furthermore, by setting the concentration of impurities in the drift region 18 to a low level, the hot carrier withstand voltage of the LDMOS 29 can be improved.

Next, a second embodiment will be described below.

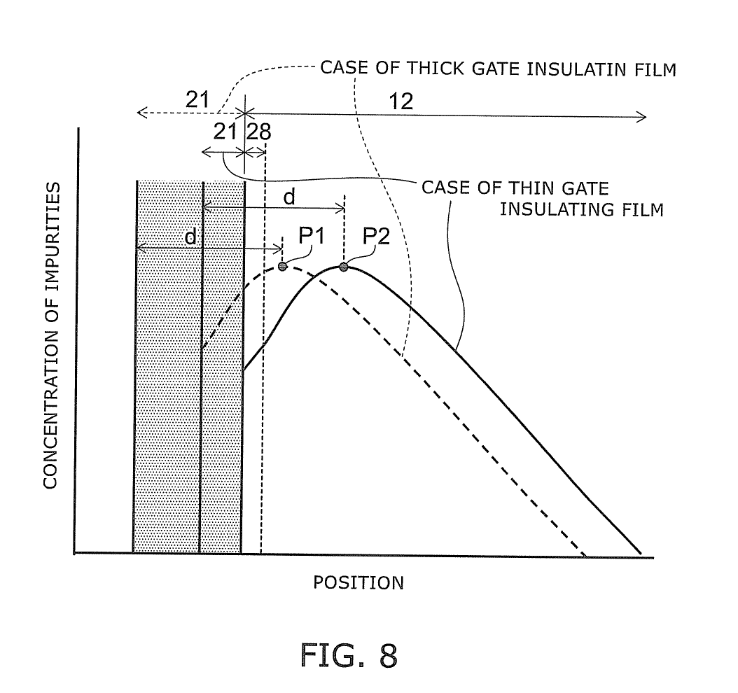

FIG. 9 is a process cross-sectional view illustrating a method for manufacturing a semiconductor device according to the embodiment.

According to the embodiment, as illustrated in FIG. 9, the gate insulating film 29 is formed, and the gate electrode 22 is formed, then the thickness of the gate insulating film 21 is uniformly thinned by wet-etching or the like. As a result, the gate insulating film 21 becomes a further thinner residual film 21a in regions outside the region directly below the gate electrode 22. Next, the resist pattern 31 is formed. The resist pattern 31 and the gate electrode 22 are used as the mask, and ion implantation of impurities for forming the channel implanting region 12 is conducted. The impurities are introduced into the p-type well 11 via the residual film 21a.

In this case, the thickness of the gate insulating film 21 at the time of the film formation is represented by a, the decreased thickness of film removed by the wet-etching is represented by b, the thickness of the residual film 21a is represented by c, and then an equation (c=a−b) is derived. Since the decreased thickness of film by the wet-etching, b, can be controlled to almost constant value, there is a positive correlation between the thickness of the gate insulating film 21 at the time of the film formation, a, and the thickness of the remained film 21a, c. That is, as the film thickness a becomes larger, the film thickness c increases. As a result, by the same operations as those in the first embodiment described above, the fluctuation of threshold value of the LDMOS 29 can be suppressed even when the thickness of the gate insulating film 21 varies. The structure, the manufacturing method, and the operations and effects of the embodiment other than described above are similar to those of the first embodiment.

Next, a third embodiment is described below.

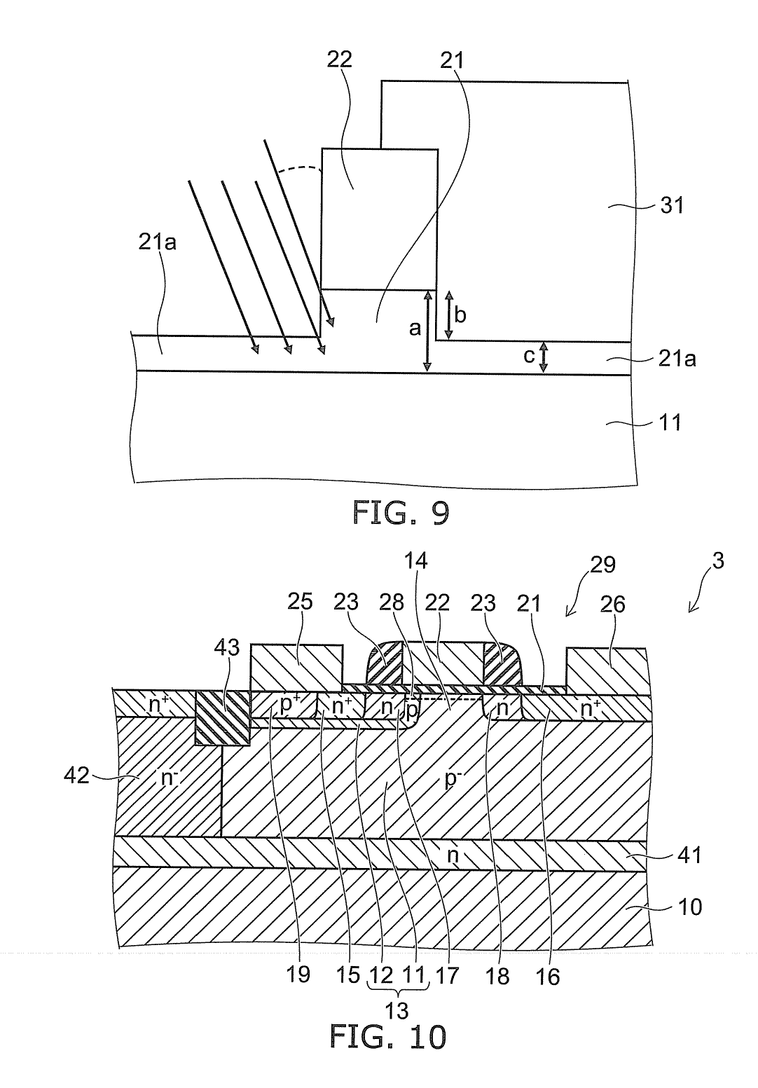

FIG. 10 is a cross-sectional view illustrating a semiconductor device according to the embodiment.

As shown in FIG. 10, in the semiconductor device 3 according to the embodiment, an n-type deep n-well (DNW) 41 is formed in an upper layer portion the semiconductor substrate 10, and an n-type well 42 and the p-type well 11 are formed on the DNW 41 contacting with each other. On the boundary region of the n-type well 42 and the p-type well 11, there is formed a shallow trench isolation (STI) 43 made of, for example, silicon oxide. The LDMOS 29 is formed above the p-type well 11. The structure, the manufacturing method, and the operations and effects of the embodiment other than described above are similar to those of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For example, the respective embodiments given above deal with an example of semiconductor made up of silicon. The invention is, however, not limited to the silicon, and other semiconductor materials can be applied. There is no limitation to single element semiconductor material, and compound semiconductors can be applied. In the respective embodiments described above, examples in which the conductivity of channel region is a p-type and the conductivities of source region and drain region are n-type has been shown. However, these conductivity types can be reversed from each other. Furthermore, an example of forming LDMOS has been shown, but the invention is not limited to LDMOS, and an ordinary MOSFET having no drift region may be formed.

According to the above-described embodiments, a semiconductor device and a method of manufacturing thereof having a small influence of the variation in processes can be achieved.

What is claimed is:

1. A semiconductor device comprising:
a semiconductor substrate;
a first conductivity-type region provided in an upper layer portion of the semiconductor substrate;
a second conductivity-type source region and a second conductivity-type drain region arranged by being separated from each other in an upper layer portion of the first conductivity-type region;
a gate insulating film provided on the semiconductor substrate; and
a gate electrode provided on the gate insulating film,
an effective concentration of impurities in a channel region corresponding to a region directly below the gate electrode in the first conductivity-type region having a maximum at an interface between the gate insulating film and the channel region, and decreasing toward a lower part of the channel region.

2. The device according to claim 1, wherein a profile of the effective concentration of impurities along a vertical direction in the channel region and in a portion of the gate insulating film corresponding to a region directly on the channel region has a peak in the gate insulating film.

3. The device according to claim 1, further comprising a drift region being in an upper layer portion of the first conductivity-type region, provided between the channel region and the drain region, contacting with the drain region, and having an effective concentration of impurities lower than an effective concentration of impurities in the drain region.

4. The device according to claim 1, further comprising an LDD region being in an upper layer portion of the first conductivity-type region, provided between the channel region and the source region, contacting with the source region, and having an effective concentration of impurities lower than an effective concentration of impurities in the source region.

5. The device according to claim 1, further comprising a channel implanting region provided in a portion on a side of the source region in the channel region, and having an effective concentration of impurities higher than an effective concentration of impurities in a portion on a side of the drain region in the channel region.

6. The device according to claim 1, wherein, in the channel region, an effective concentration of impurities in a portion on a side of the source region is higher than an effective concentration of impurities in a portion on a side of the drain region.

7. The device according to claim 1, wherein a portion of the region directly below the gate electrode in the gate insulating film has a larger thickness than portions other than the portion of the region directly below the gate electrode in the gate insulating film.

8. The device according to claim 1, further comprising a second conductivity-type deep well provided in an upper layer portion of the semiconductor substrate,
the first conductivity-type region being provided in an upper layer portion of the deep well.

9. The device according to claim 8, further comprising:
a second conductivity-type region provided in an upper layer portion of the deep well and contacting with the first conductivity-type region; and
a device isolation insulating film provided in an upper portion of a boundary region between the first conductivity-type region and the second conductivity-type region.

10. A method for manufacturing a semiconductor device, comprising:
forming a first conductivity-type region in an upper layer portion of a semiconductor substrate;
forming a gate insulating film on the semiconductor substrate;
forming a gate electrode on the gate insulating film;
forming a channel implanting region by introducing impurities into a region directly below the gate electrode in the first conductivity-type region via the gate insulating film; and
forming a second conductivity-type source region and a second conductivity-type drain region in regions on both sides of a region corresponding to the region directly below the gate electrode in an upper layer portion of the first conductivity-type region,
the introducing the impurities being conducted so that a profile of a concentration of the impurities along a vertical direction has a peak in the gate insulating film.

11. The method according to claim 10, wherein the introducing the impurities is conducted from a direction tilted with respect to a direction normal to an upper surface of the semiconductor by using the gate electrode as a mask.

12. The method according to claim 11, wherein the introducing the impurities is conducted from a direction tilted toward a region having the source region to be formed, the direction tilted relative to a direction normal to the upper surface of the semiconductor substrate.
